(19) United States
(12) Patent Application Publication
(10) Pub. No.: US 2007/0274142 A1
(43) Pub. Date: Nov. 29, 2007

(54) Method and device of generating test circuit for semiconductor device

(76) Inventor: Ryota Nishikawa, Shiga (JP)

Correspondence Address: MCDERMOTT WILL & EMERY LLP, 600 13TH STREET, NW, WASHINGTON, DC, 20005-3096, US

(21) Appl. No.: 11/797,545

(22) Filed: May 4, 2007

(30) Foreign Application Priority Data
May 11, 2006 (JP) 2006-132377

(51) Int. Cl. G11C 29/00

(52) U.S. Cl. 365/200

(57) ABSTRACT

The test circuit generating method comprises the steps of: a first step for obtaining memory information containing structural information of the memory; a second step for obtaining failure judgment bit information that designates a judgment target bit as a target of failure judgment from entire output bits of the memory; and a third step for generating a failure judgment control circuit which performs failure judgment on the memory by using only the judgment target bit designated in the failure judgment bit information, referring to the memory information.

### BACKGROUND OF THE INVENTION

1. Field of the Invention

The present invention relates to a method and a device for generating a test circuit to test a semiconductor memory in a semiconductor integrated circuit that comprises a built-in semiconductor memory, and to a semiconductor integrated circuit having a test circuit constituted by the test circuit generating method.

2. Description of the Related Art

Recently, as disclosed in Japanese Published Patent Literature (Japanese Unexamined Patent Publication H11-260096), there have been an increased number of cases where a test circuit that can perform self-inspection in accordance with a loaded memory, is mounted so as to test the memory loaded on the semiconductor integrated circuit. In general, the capacity and the type of the memory vary with respect to each semiconductor integrated circuit, so that it is necessary to design and mount the test circuit according to the memory that is loaded in each semiconductor integrated circuit. In the meantime, as shown in a literature (“Embedded Memory Test (EMT)” by Logic Vision, Inc. <URL:http://www.logicvision.com/Products/Silicon_Test/Memory/EMT_Datasheet.pdf> (FIG. 1, FIG. 2)), it is possible to automatically generate a test circuit based on the information of the memory to be loaded, such as the type, the structure and the capacity. By using such technique freely, the number of steps for designing the test circuit and the designing term can be reduced.

Regarding a system achieved by a semiconductor integrated circuit, there are cases where it is used in such a manner that specific bits are not used (unused bits) or used in such a manner that a fixed value (set value of “0” or “1”) is always outputted. Even in such cases, the conventional circuit performs failure judgment by carrying out a test under a state where the expected values are set as both values of “0” and “1” for all the bits.

However, when there is a failure in a bit that has no influence on the semiconductor integrated circuit under a normal operation, it is possible to misjudge it as a failure of the semiconductor integrated circuit itself, irrespective of having no relation for the operation essentially. That is, if the test is carried out on that bit, it is judged as a failure generated in that bit. However, this bit is an unused bit to start with, so that there is no influence upon the actual operation of the semiconductor integrated circuit even though there is a failure. Nevertheless, it is misjudged that the semiconductor integrated circuit has a failure, which results in deteriorating the yield.

### SUMMARY OF THE INVENTION

Therefore, the main object of the present invention is to provide a method and a device for generating a test circuit for a semiconductor integrated circuit and its semiconductor integrated circuit, in a semiconductor integrated circuit for avoiding misjudgment and improving a yield in the test even under the circumstances where even a good product is judged as a fault in the conventional technique, in the test when there are unused bits or there are fixed value bits from which “0” or “1” is outputted.

In order to solve the aforementioned issues, a method for generating a test circuit according to the present invention for testing a semiconductor integrated circuit that comprises a memory. The method comprises the steps of:
a first step for obtaining memory information containing structural information of the memory;
a second step for obtaining failure judgment bit information that designates a judgment target bit taken as a target of failure judgment from entire output bits of the memory; and
a third step for generating a failure judgment control circuit that performs failure judgment of the memory by using only the judgment target bit designated in the failure judgment bit information, referring to the memory information.

A test circuit generating device of the present invention which corresponds to this test circuit generating method comprises execution devices for each step that corresponds to the method.

It is preferable to perform the second step and the third step in a same step, and to perform the first step and the second step in a same step.

Here, memory information is the information such as type, structure, and capacity thereof. For example, there are the number of columns (column number), the number of rows (row number), and the data width of every output data of 1 bit. The failure judgment bit information designates the failure judgment target bit desired to set as the target of the failure judgment. The failure judgment control circuit has a function of eliminating the failure judgment target when a prescribed condition is fulfilled, e.g. when there is an unused bit or when there is a fixed-value bit from which the “0” or “1” is outputted at all times. Only the judgment target bit designated in the failure judgment bit information is used to generate such failure judgment control circuit.

A semiconductor integrated circuit that includes the test circuit generated by this test circuit generating method comprises: a memory;
a comparator for comparing output data of each bit in the memory with an expected value thereof; and
a failure judgment control circuit for performing output control of comparison results for each bit obtained by the comparator, based on the bit that is designated as judgment targets among entire output bits of the memory in the failure judgment bit information that designates the judgment target bit taken as the target of the failure judgment. For this structure, it is possible to refer to FIG. 5 and FIG. 7 according to embodiments to be described later.

As just described, the failure judgment control circuit generated by using only the failure judgment target bit forms a test circuit that excludes the bit that is not used in a normal operation from the target of failure judgment. As a result, it is possible to eliminate fault of the semiconductor integrated circuits due to the failures in the unused bit. That is, for the semiconductor circuit that is misjudged as fault in the conventional technique due to the failure detected at the unused bit even though it is a fine product, it is possible to handle such circuit properly as a fine product. Herewith, the yield can be improved.

Further, there is such an embodiment that, in the third step of the method or the device for generating the test circuit in the above-described semiconductor integrated circuit, a register for storing the failure judgment bit information is further generated. The semiconductor integrated circuit that corresponds to this further comprises a register that stores the failure judgment bit information in the aforementioned structure.

In this case, the test circuit obtained by generating the register for storing the failure judgment bit information is capable of performing much faster operation within the range of frequency specification of the semiconductor integrated circuit, compared to a test circuit where the failure judgment bit information is obtained from the outside. Further, it becomes possible to store the failure judgment bit information from the outside to the register after designing the semiconductor integrated circuit. Therefore, it is possible to perform more flexible testing through changing the failure judgment bit information.

Furthermore, when the failure judgment bit information is obtained not in the second step but in the first step, the failure judgment control circuit generated in the third step becomes the one corresponded to the judgment target bit. The failure judgment bit information is inputted in the first step, so that the failure target bit is known in advance at the time of generating the test circuit. As a result, it is possible to generate the optimum failure judgment control circuit that takes only the signal of the judgment target bit as the target. It is unnecessary to constitute this failure judgment control circuit as targeted on the entire bits. Herewith, the structure of the test circuit is simplified, so that the area of the test circuit and the power consumption can be reduced.

Incidentally, the number of bits necessary for storing the addresses is normally smaller than the number of bits for storing the data. That is, there are unused bits with respect to the addresses, and testing may be omitted for the unused bits. It is the reason because testing performed on the entire bits causes not only a waste but also unnecessary deterioration in the yield.

Consequently, there is such an embodiment that, in the test circuit generating method or device where the failure judgment bit information is inputted in the above-described first step, failure judgment bit information determined based on the address map used in the system achieved by the semiconductor integrated circuit, is used as the failure judgment information in the first step, assuming that the memory stores memory addresses based on an address map of a system achieved by the semiconductor integrated circuit.

In this case, it is possible to efficiently generate the test circuit that excludes the unused bit from the failure judgment target by determining the bit column as the target of failure judgment based on the address map.

Further, a method for generating a test circuit for a semiconductor integrated circuit according to the present invention is a method for generating a test circuit that performs the test of a semiconductor integrated circuit that comprises a memory. The method comprises the steps of:
a first step for obtaining memory information containing structural information of the memory;
a second step for obtaining fixed-value bit information that designates a fixed-value bit where an output value from the memory becomes a fixed value of either “0” or “1”, and obtaining fixed value information that designates a fixed value that is an output value of the fixed-value bit; and
a third step for generating a failure judgment control circuit that performs failure judgment when an expected value of the fixed-value bit is consistent with the fixed value designated in the fixed value information, referring to the memory information.

A test circuit generating device of the present invention that corresponds to this test circuit generating method comprises execution devices for each step that corresponds to the method.

The semiconductor integrated circuit that corresponds to this test circuit generating method comprises:
a memory;
a comparator for respectively comparing output data of each bit in the memory with an expected value thereof; and
a failure judgment control circuit for selectively letting through a comparison result that is outputted by the comparator in accordance with a judgment target bit in failure judgment bit information that designates a judgment target bit taken as a target of failure judgment.

The value of each bit in the fixed-value bit information is a value indicating whether or not the bit is a fixed-value bit. For this structure, it is possible to refer to FIG. 10 according to the embodiment that is described later.

In a structure like this, it is possible to generate a test circuit that eliminates from the target of failure judgment with respect to the fixed value bit as a particular bit from which “0” or “1” is outputted at all times under a normal operation. That is, even if it is judged as a failure when the test result indicates that the expected value becomes the inversed logic of the fixed value, there is no influence on the operation since the fixed value is outputted at all times under the normal operation. Accordingly, it is possible to handle the fine semiconductor integrated circuit as a fine product properly, which is misjudged as an inferior product in a circuit generated by the conventional technique. Thus, the yield can be improved.

There is also such an embodiment that, in the second step, further obtained is failure judgment bit information that designates a judgment target bit taken as a target of failure judgment from entire output bits of the memory; and
in the third step, the failure judgment control circuit is generated when an expected value of the fixed-value bit is consistent with a fixed value designated in the fixed value information, and the judgment target bit in the failure judgment bit information is valid.

The semiconductor integrated circuit corresponding to such embodiment comprises: a memory;
a comparator for respectively comparing output data of each bit in the memory with an expected value thereof; and
a failure judgment control circuit, wherein the failure judgment control circuit comprises:
a fixed-value gate circuit for respectively comparing a fixed value of each bit in fixed value information that designates an output value of a fixed-value bit outputted from the memory to be fixed at either “0” or “1”, with an expected value thereof;
a fixed-value bit gate circuit for controlling output of the fixed-value gate circuit, based on a value of each bit designated in fixed-value bit information that designates the fixed-value bit; and
a judgment target gate circuit for controlling output of a comparison result obtained by the comparator, based on an output value of the fixed-value bit gate circuit and judgment target bit in the failure judgment bit information. For this structure, it is possible to refer to FIG. 10 according to the embodiment that is described later.

Herewith, elimination of the bit from the failure judgment target can be performed doubly on the basis of both the unused bit and the particular bit. Therefore, the structure of the test circuit can be more simplified, and the area of the test circuit and the power consumption can be reduced.

There is also such an embodiment that, in the third step of the method or the device for generating the test circuit for the above-described semiconductor integrated circuit, a register for storing the fixed-value bit information and the fixed value information is generated.

In this case, the test circuit obtained by generating the register circuit for storing the fixed-value bit information and the fixed value information is capable of performing much faster operation within the range of frequency specification of the semiconductor integrated circuit, compared to a test circuit for performing a test through inputting the failure judgment bit information from the outside. Further, it is possible to store the failure judgment bit information from the outside to the register after designing the semiconductor integrated circuit. Therefore, it is possible to perform more flexible testing through changing the failure judgment bit information.

Further, a method for generating a test circuit for a semiconductor integrated circuit according to the present invention comprises the steps of:
a first step for obtaining memory information containing structural information of the memory;
a second step for obtaining fixed-value bit information that designates a fixed-value bit where an output value of the memory becomes a fixed value of either “0” or “1” from entire output bits of the memory, and obtaining fixed value information which designates a fixed value that is an output value at the fixed-value bit from the entire output bits of the memory; and
a third step for generating a failure judgment control circuit that performs failure judgment of the memory by using the fixed-value bit information and the fixed value information, while referring to the memory information. A test circuit generating device of the present invention that corresponds to this test circuit generating method comprises execution devices for each step that corresponds to the method.

In the semiconductor integrated circuit that corresponds thereto has the structure of the above-described semiconductor integrated circuit, wherein processing of the fixed-value gate circuit and processing of the fixed-value bit gate circuit is both omitted for a bit where its value in the fixed-value bit information and the fixed value thereof in the fixed value information are both valid, and the fixed value of the relevant bit is treated as output data thereof. For this structure, it is possible to refer to FIG. 11 according to the embodiment that is described later.

In this case, when the subject bit has the fixed value of “1”, the output of the fixed-value bit gate circuit becomes consistent with the expected value thereof. Thus, there is no influence on the result even if the fixed-value gate circuit and the fixed-value bit gate circuit are omitted. By constituting like this, it is possible to optimize (reduce the circuit elements) the failure judgment control circuit at the time of generating the test circuit. Therefore, more reduction in the circuit area and the power consumption can be expected.

Further, in the method or the device for generating the test circuit in the above-described semiconductor integrated circuit, there is also such an embodiment that, in the first step, a bit whose value becomes either “0” or “1” at all times in all of the memory addresses that are possible to be stored in the memory, is inputted as the fixed-value bit, assuming that the memory stores memory addresses based on an address map of a system.

In the case of the memory that stores the memory address like this, the information of the bit whose value is always “0” or “1” can be discriminated from the information of the address map. Therefore, like the above-described case, it becomes easy to generate the test circuit when the addresses are stored in the memory.

More preferably, in the third step, a comparator having a function for comparing only output of the judgment target bit with an expected value thereof may be generated through using the judgment target bit in the failure judgment bit information.

In the semiconductor integrated circuit corresponding thereto having the above-described structure, output data from a bit that does not correspond to the judgment target bit is neglected to be inputted to the comparator, and output control of the failure judgment control circuit to the comparator at a bit corresponding to the judgment target bit is omitted. For this structure, it is possible to refer to FIG. 13 according to the embodiment that is described later.

By comparing only the output of the judgment target bit in this manner, it is possible not only to omit the structure of the failure judgment control circuit without necessity of operation but also to omit the structure of the comparator without necessity of operation. Therefore, the circuit area and the power consumption can be further reduced.

More preferably, in the third step, a comparator for excluding a comparison between an output value of the fixed-value bit and its expected value may be generated as the comparator by using the fixed-value bit in the fixed-value bit information.

In the semiconductor integrated circuit corresponding thereto having the above-described structure, with respect to a bit whose value in the fixed-value bit information and the fixed value in the fixed value information are both valid, processing of the fixed-value gate circuit and processing of the fixed-value bit gate circuit is both omitted, and processing of the comparator at the bit is substituted with processing performed by a logic inverting circuit. For this structure, it is possible to refer to FIG. 14 of the embodiment that is described later.

By constituting as described above, comparison of the expected value is not performed at the fixed-value bit, and the inconsistency detection circuit is replaced with a logic inverting circuit (inverter). Thus, more reduction in the circuit area and the power consumption can be achieved.

According to the present invention, generated is a test circuit that excludes the bit that is not used in the normal operation, from the failure judgment target. Thus, it is possible to handle the fine semiconductor integrated circuit as a fine product in the proper manner, that is misjudged as a fault by the test circuit generated by the conventional technique. Herewith, it is possible to improve the yield of the semiconductor integrated circuits, compared to that of the conventional technique.

Further, it is possible to generate a test circuit that does not judge as a fault with respect to the particular bit where “0” or “1” is outputted at all times under a normal operation, when the value outputted at the time of the normal operation can be outputted properly. Thus, it is possible to handle the fine semiconductor integrated circuit as a fine product in the proper manner, which is misjudged as a fault by the test circuit generated by the conventional technique. Herewith, like the above-described case, it is possible to improve the yield of the semiconductor integrated circuits.

Furthermore, it is also possible to omit the comparing processing itself performed by the comparator for the unused bit and the particular bit. Therefore, reduction in the circuit area and cutback in the power consumption can be expected.

The method for generating the test circuit for the semiconductor integrated circuit according to the present invention can control necessity or un-necessity on execution of the test by a bit unit of the memory that is loaded on the semiconductor integrated circuit. Thus, it is effectively used for self-inspection of the semiconductor integrated circuit. In particular, it is specifically effective for the circuit with a cache, such as a processor, and it can be applied to the test of the tag part for storing the address, and TLB (Translation Look aside Buffers).

### BRIEF DESCRIPTION OF THE DRAWINGS

Other objects of the present invention will become clear from the following description of the preferred embodiments and the appended claims. Those skilled in the art will appreciate that there are many other advantages of the present invention by embodying the present invention.

FIG. 1 is a flowchart showing the procedure of the processing of a method for generating a test circuit for a semiconductor integrated circuit according to a first embodiment of the present invention;

FIG. 2 is a constitutive diagram of a memory that is loaded on the semiconductor integrated circuit according to the first embodiment of the present invention;

FIG. 3 is an illustration showing an example of failure judgment bit information according to the first embodiment of the present invention;

FIG. 4 is a block diagram showing a schematic structure of the semiconductor integrated circuit that includes a test circuit according to the first embodiment of the present invention;

FIG. 5 is a block circuit diagram showing a structure of the semiconductor integrated circuit including a test circuit that is generated by a test circuit generating method according to the first embodiment of the present invention;

FIG. 6 is a block diagram showing a structure of the semiconductor integrated circuit including a test circuit that is generated by a test circuit generating method according to a second embodiment of the present invention;

FIG. 7 is a block diagram showing a structure of the semiconductor integrated circuit including a test circuit that is generated by a test circuit generating method according to a third embodiment of the present invention;

FIG. 8 shows an address map according to a fourth embodiment of the present invention;

FIG. 9 is an illustration showing an example of fixed-value bit information and fixed value information according to a fifth embodiment of the present invention;

FIG. 10 is a first block diagram showing a structure of the semiconductor integrated circuit including a test circuit that is generated by a test circuit generating method according to the fifth embodiment of the present invention;

FIG. 11 is a second block diagram showing a structure of the semiconductor integrated circuit including a test circuit that is generated by a test circuit generating method according to the fifth embodiment of the present invention;

FIG. 12 shows an address map according to a sixth embodiment of the present invention;

FIG. 13 is a block circuit diagram showing a structure of the semiconductor integrated circuit including a test circuit that is generated by a test circuit generating method according to a seventh embodiment of the present invention;

FIG. 14 is a block circuit diagram showing a structure of the semiconductor integrated circuit including a test circuit that is generated by a test circuit generating method according to an eighth embodiment of the present invention; and

FIG. 15 is a system constitution diagram of a test circuit generating device for a semiconductor integrated circuit according to a ninth embodiment of the present invention.

### DETAILED DESCRIPTION OF THE INVENTION

Hereinafter, embodiments of a test circuit generating method in a semiconductor integrated circuit according to the present invention and a semiconductor integrated circuit obtained will be described in detail. There are specific test circuit generating methods suited for various modes of memories.

### First Embodiment

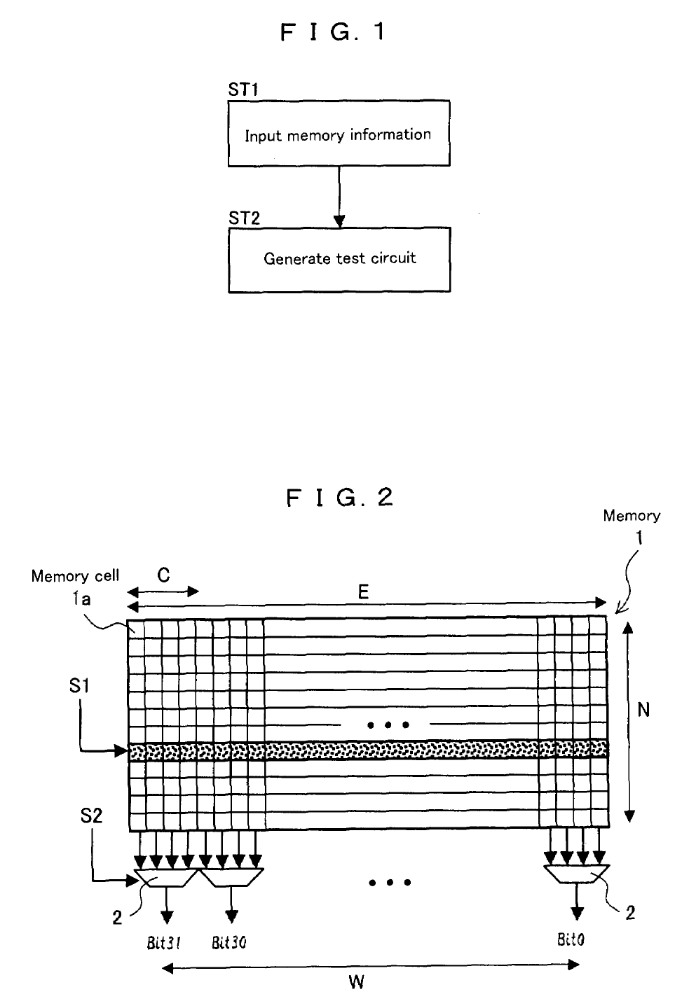

FIG. 1 is a flowchart showing the procedure of the processing of a method for generating a test circuit for a semiconductor integrated circuit according to a first embodiment of the present invention. The test circuit generating method of this embodiment comprises a first step ST1 for inputting memory information that is the information regarding the constitution, structure of the memory, the testing method and the like, and a second step ST2 for performing a generation of a test circuit (failure judgment control circuit/comparator) referring to the memory information.

FIG. 2 illustrates a memory 1 with the output of 32 bits, as an example of the memory loaded on a semiconductor integrated circuit. In FIG. 2, reference numeral 1a is a memory cell of 1 bit. “C” indicates the number of columns in an output of 1 bit, and four columns constitute the output of 1 bit in this example. “E” indicates the bit width of the memory 1, called an entry. In this example, it is set as 128 bits. A series of memory cell 1a group with the width of entry E are lined in N-number of rows in the vertical direction to form the memory 1.

When a data request for the memory 1 is generated, the entry selected by a memory index S1 becomes the readout target. The memory 1 has a series of (thirty-two selectors in this example) selectors 2 in the output part. For the data of the readout target entry, the data of one of the four columns is selected according to a selection signal S2, and the data with the width W is outputted from the memory 1. In this example, the data width W is 32 bits. The column number C, the row number N, and the data width W are inputted in the first step ST1 as the memory information that shows the structural information of the memory. In addition, the definition of the test pattern in testing the memory, the procedure of the test and the like, are inputted as the memory information.

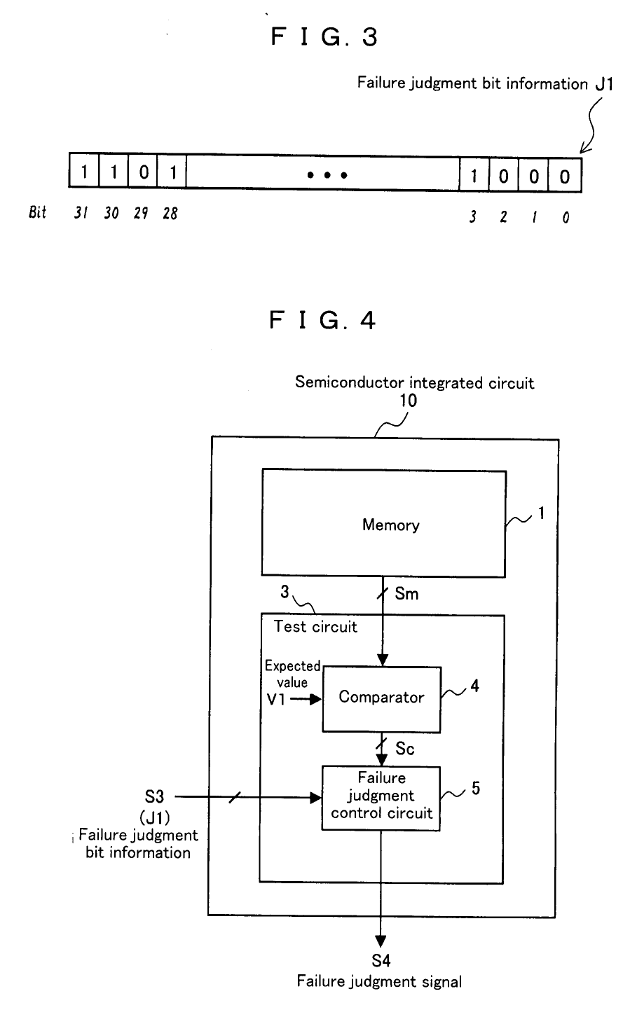

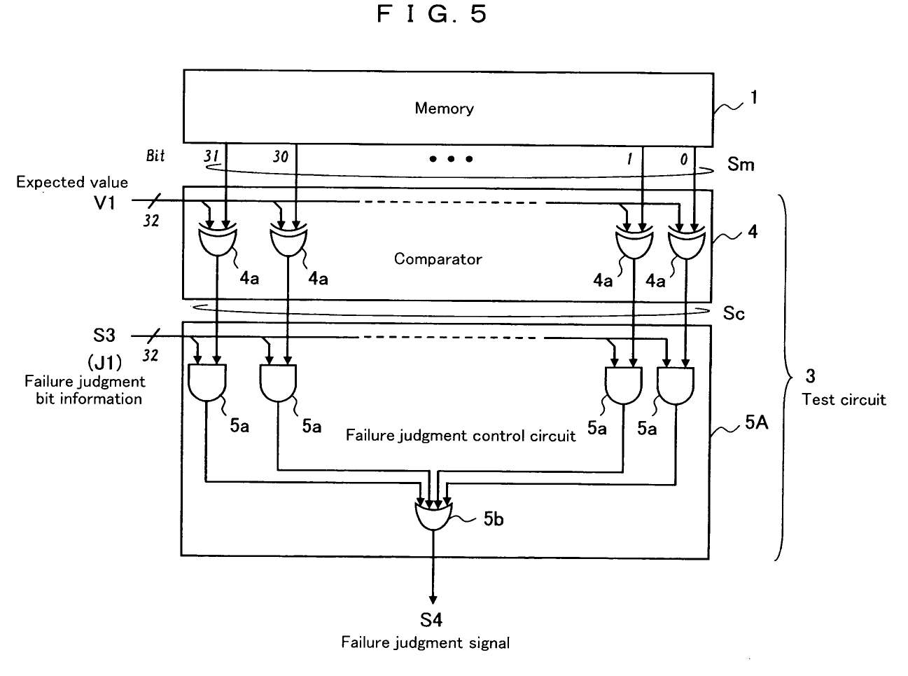

Further, in the second step ST2, generated is a failure judgment control circuit 5 (FIG. 4 and FIG. 5) for performing failure judgment of the memory 1 by using the failure judgment bit information J1 shown in FIG. 3. The failure judgment bit information J1 is the information having the same bit width as that of the data outputted from the memory 1, and “0” or “1” is stored in each bit.

FIG. 3 shows an example of the judgment target bit in testing the memory 1 with 32-bit width that is shown in FIG. 2. The numerical value defined in each bit indicates whether or not it is the target bit of the failure judgment. “1” indicates that it is the target bit of the failure judgment, and “0” indicates that it is not the target of the failure judgment. It may also be defined in the inverse logic.

FIG. 4 is a block diagram showing the structure of a semiconductor integrated circuit 10 that includes a test circuit 3 generated by the second step ST2. In FIG. 4, reference numeral 4 is a comparator, and 5 is a failure judgment control circuit. The test circuit 3 is constituted with the comparator 4 and the failure judgment control circuit 5. The comparator 4 compares the output data Sm from the memory 1 and a prescribed expected value V1 by each bit. The failure judgment control circuit 5 performs exclusion processing from the failure judgment target to the inconsistency judgment data Sc that is a result of comparison carried out by the comparator 4. The failure judgment target excluding processing is carried out when such a prescribed condition that there exists an unused bit is fulfilled.

In the second step ST2, first, the failure judgment bit information J1 is inputted. The failure judgment bit information J1 is the information for designating the judgment target bit taken as a target of failure judgment from all the output bits of the memory 1. Further, in the second step ST2, the failure judgment control circuit 5 is generated referring to the memory information such as the bit width inputted in the first step ST1. The failure judgment control circuit 5 is constituted on the assumption that the failure judgment of the memory 1 is carried out by using only the judgment target bit in the failure judgment bit information J1.

The failure judgment control circuit 5 has the following functions. That is, first, the comparator 4 performs inconsistency judgment between the output data Sm from the memory 1 and the expected value V1. The comparator 4 outputs the inconsistency judgment data Sc indicating the judgment result to the failure judgment control circuit 5. In the inconsistency judgment data Sc, the bit “1” indicates inconsistency and the bit “0” indicates consistency respectively.

If the circuit outputs the inconsistency judgment data Sc as it is, it is the same circuit as that of the conventional technology. It is the failure judgment circuit 5 that it has a function of excluding the inconsistency judgment data Sc on the unnecessary bit (unused bit) recognized as unnecessary to do the test from the entire bits so as to exclude the test at the unused bit.

A judgment target bit signal S3 along with the failure judgment bit information J1, and the inconsistency judgment data Sc from the comparator 4 are inputted to the failure judgment control circuit 5. The failure judgment control circuit 5 generates and outputs the inconsistency judgment data Sc which designates only the bits where “1” is set in the failure judgment bit information J1 among the inconsistency judgment data Sc, i.e. the inconsistency judgment data Sc that designates only the bits that correspond to the judgment target bits as the targets of failure judgment. The failure judgment bit information J1 designates the judgment target bit that is desired to set as the target of failure judgment. The failure judgment control circuit 5 with the function described above is generated in the second step ST2.

The judgment target bit signal S3 along with the failure judgment bit information J1 is inputted to the failure judgment control circuit 5 from the outside of the semiconductor integrated circuit 10. The failure judgment control circuit 5 performs failure judgment by excluding the failure judgment in the unused bit, based on the inconsistency data Sc from the comparator 4 and the failure judgment bit information J1 (contained in the judgment target bit signal S3) which is inputted from the outside. The failure judgment control circuit 5 then generates and outputs the result thereof as a failure judgment signal S4.

FIG. 5 is a block circuit diagram for showing the details of the comparator 4 and a failure judgment control circuit 5A. In FIG. 5, reference numeral V1 indicates the expected value used in the comparing processing, and the expected value V1 is generated inside the test circuit 3. The comparator 4 compares the output data Sm from the memory 1 and the expected value V1 using inconsistency detection circuit 4a. The comparator 4 outputs the inconsistency judgment data Sc that becomes active when the result indicates the inconsistency to the failure judgment control circuit 5A. Here, an exclusive OR circuit (ExOR) is used as the inconsistency detection circuit 4a.

The inconsistency judgment data Sc from the comparator 4 and the judgment target bit signal S3 are inputted to the failure judgment control circuit 5A. The failure judgment control circuit 5A comprises a judgment target gate circuit 5a and a failure judgment output circuit 5b. At each bit, the judgment target gate circuit 5a selects the inconsistency data Sc, handling the failure judgment bit information J1 contained in the judgment target bit signal S3 as a through control signal. The failure judgment output circuit 5b puts together the outputs of the judgment target gate circuits 5a for the entire bits and outputs it as a failure judgment signal S4. An AND circuit (AND) is used as the judgment target circuit 5a herein, and an OR circuit (OR) is used as the failure judgment output circuit 5b. Assuming that the bit number of the inconsistency detection circuit 4a constituting the comparator 4 is 32 bits, the judgment target gate circuit 5a in the failure judgment control circuit 5A is also provided as much as 32 bits.

At the bit defined as “0” in the failure judgment bit information J1, the output of the judgment target gate 5a constituted with the OR circuit becomes “0” at all times. Thus, it can be excluded from the target of failure judgment. Meanwhile, at the bit defined as “1” in the failure judgment bit information J1, the inconsistency judgment data Sc from the comparator 4 is reflected as it is upon the output of the failure judgment gate circuit 5a. Therefore, it is possible in this case to judge the failure based on the comparison result obtained by the comparator 4. This is irrelevant from the fact that the result of comparison between the output data Sm from the memory 1 and the expected value V1 performed by the comparator 4 at each bit is “0” or “1”.

Even if the inconsistency detection circuit 4a carries out inconsistency detection in the comparator 4 and finds a bit that is indicated as “1” in the inconsistency judgment data Sc, the inconsistency judgment data Sc from the inconsistency judgment circuit 4a for that bit is not employed if the bit is excluded from the target of failure judgment based on the failure judgment information J1=“0”. Herewith, the number of misjudgments can be reduced.

Through comparing only the judgment target bits based on the failure judgment bit information J1, the defect number of the semiconductor integrated circuits due to the failures of the bits out of the failure judgment targets can be decreased, compared to the case of using the conventional technique where the failures are judged by performing comparison on the entire bits at all times. Herewith, the yield can be improved.

The structures of the comparator 4 and the failure judgment control circuit 5A are not limited to the circuit structures shown in FIG. 5. It is possible to employ other arbitrary forms as long as it has the similar functions.

As described above, in the test circuit generating method according to this embodiment forms a test circuit, the failure judgment control circuit generated by using only the judgment target bit constitutes a test circuit that does not judge it as a failure with respect to the bit that is not used under a normal operation. As a result, it is possible to eliminate a fault of the semiconductor integrated circuits due to the failures at the unused bit. That is, for the semiconductor circuit that is misjudged by the conventional technology as an inferior product due to the failure at the unused bit even though it is a fine product, it is possible to handle such circuit properly as a fine product. Herewith, the yield can be improved.

### Second Embodiment

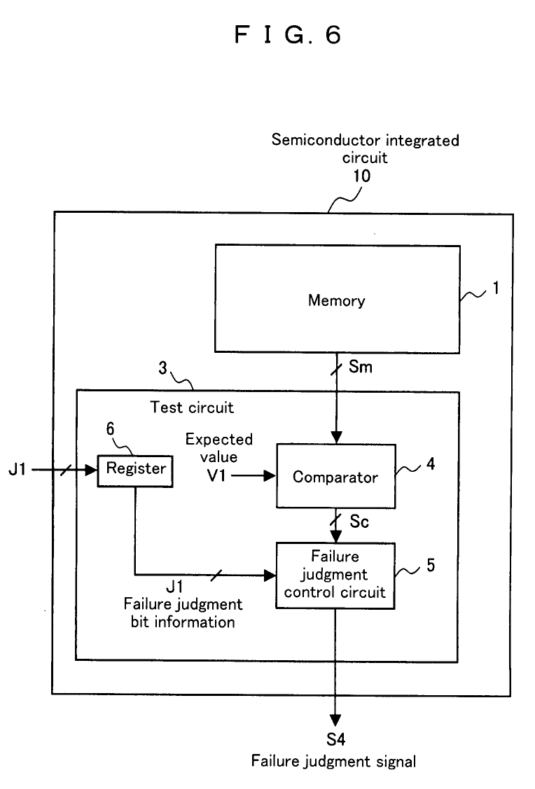

FIG. 6 is a block diagram showing the structure of a semiconductor integrated circuit that includes a test circuit 3 generated by a test circuit generating method according to a second embodiment of the present invention. In FIG. 6, the same reference numerals as those of the first embodiment shown in FIG. 4 indicate the same structural elements.

The test circuit generating method for a semiconductor integrated circuit according to the second embodiment is based on the first embodiment wherein a register 6 for storing the failure judgment bit information J1 is generated in the second step ST2.

The test circuit 3 comprises the register 6. The register 6 is generated in the second step ST2 in order to store the failure judgment bit information J1 generated in the second step ST2. The register 6 is capable of storing the information supplied from the outside of the semiconductor integrated circuit 10. Other structures are the same as those of the first embodiment, so the descriptions thereof are omitted.

The test circuit 3 generated by the test circuit generating method of this embodiment comprises the register 6 for storing the failure judgment bit information J1. Thus, compared to a test circuit to which the failure judgment bit information J1 is inputted from the outside, much faster operation can be achieved within the range of frequency specification of the semiconductor integrated circuit. Further, it is possible to input the failure judgment bit information J1 to the register 6 from the outside, after designing the semiconductor integrated circuit. Therefore, it is possible to perform more flexible testing through changing the failure judgment bit information J1.

### Third Embodiment

The test circuit generating method for a semiconductor integrated circuit according to a third embodiment is based on the first embodiment, wherein the failure judgment bit information J1 is inputted in the first step ST1 instead of the second step ST2.

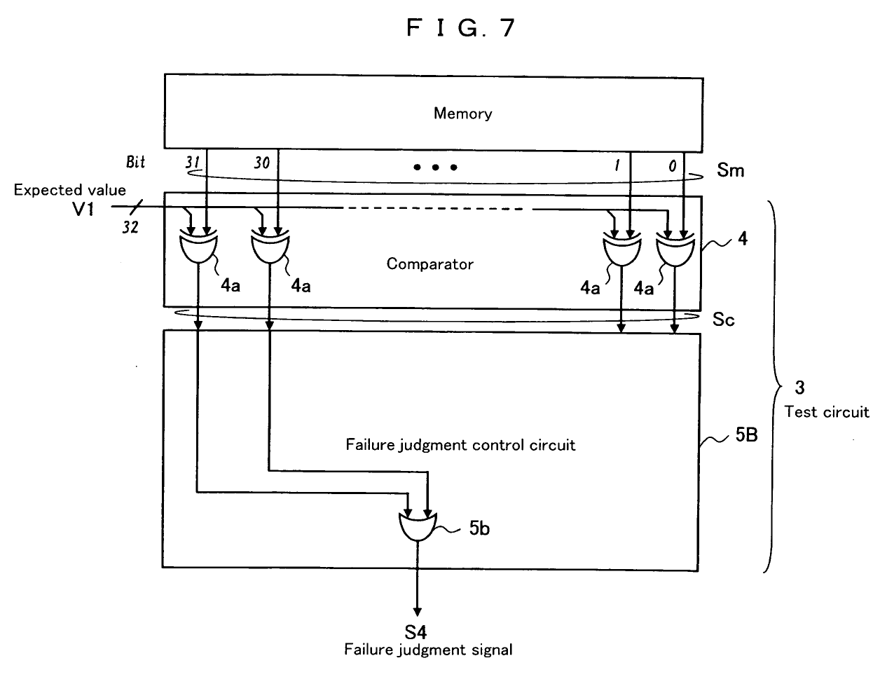

FIG. 7 is a block diagram showing the structure of a semiconductor integrated circuit that includes a test circuit 3 generated by a test circuit generating method according to the third embodiment of the present invention. In this embodiment, regarding a failure judgment control circuit 5B of the test circuit 3, all the judgment target gate circuits 5a constituted with the AND circuits shown in FIG. 5 of the first embodiment are omitted, and the input of the failure judgment output circuit constituted with the OR circuit is also simplified. That is, the failure judgment output circuit 5b is constituted with the OR circuit based on a simple structure with decreased number of bits. The structure in FIG. 5 has the input of 32 bits, and the structure thereof is complicated.

All the judgment target circuits 5a can be omitted and the bit number of the input of the failure judgment output circuit 5b can be reduced because the failure judgment control circuit 5B is constituted so as to perform failure judgment only in the judgment target bits since the judgment target bit of the memory 1 is known in advance. The failure judgment bit information J1 is inputted in the first step ST1 so that the failure judgment control circuit 5B with such structure can be generated in the second step ST2.

In FIG. 7, specifically, the failure judgment control circuit 5b is constituted with an OR circuit with the input of 2 bits, which takes the logic sum of the output of the inconsistency detection circuit 4a at the 31st bit of the comparator 4 and the output of the inconsistency detection circuit 4a at the 30th bit, when it is defined in the failure judgment bit information J1 that the 31st bit and the 30th bit are “1” that defines the judgment target bits, and all of the 0th bit to the 29th bit are “0” that defines the unused bits. In the case of the memory 1 shown in FIG. 7, it is not necessary to use the failure judgment bit information J1 in the failure judgment control circuit 5B, since the judgment target bits are already known. Thus, the judgment target gate circuits 5a equal to the entire bits, which are used in the case of FIG. 5, are not used at all. Furthermore, for the bit whose judgment target bit is “0”, it is unnecessary to wire the output terminal of the inconsistency detection circuit 4a in the comparator 4 to the failure judgment control circuit 5b. That is, the circuit elements and the wirings between the elements are simplified largely. As a result, the circuit area and the power consumption can be reduced.

The failure judgment control circuit 5B shown in FIG. 7 is merely an example. The failure judgment control circuit generated according to the test circuit generating method of the present invention is not limited to that structure.

### Fourth Embodiment

A fourth embodiment of the present invention corresponds to the case where a semiconductor integrated circuit is designed by using a memory that includes the unused bits on the system. The memory space can be considered as separate areas, i.e. an area for storing the data and an area for storing the addresses used by the system. The number of bits necessary for storing the addresses is normally smaller than the number of bits for storing the data. That is, there are unused bits among those used for the addresses, and testing can be omitted for the unused bits. Testing performed on the entire bits is not only a waste but also causes unnecessary deterioration in the yield due to misjudgment.

The test circuit generating method for the semiconductor integrated circuit according to the fourth embodiment uses the failure judgment bit information determined based on the address map used in the system that is achieved by the semiconductor integrated circuit, as the failure judgment bit information J1 that is inputted in the first step ST1, in the above-described third embodiment. And, the memory where the test circuit generated by the test circuit generating method of this embodiment becomes the target stores the addresses of the system.

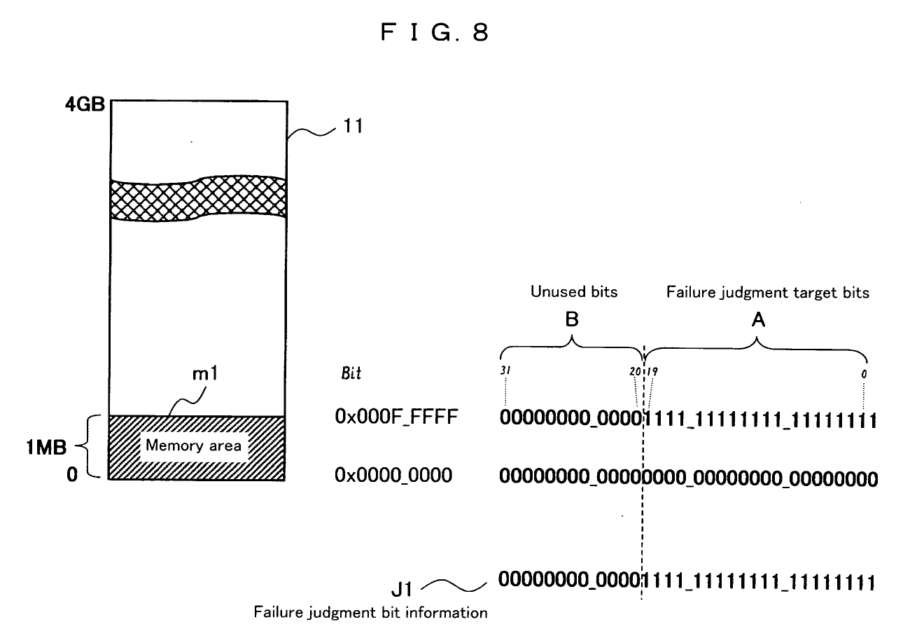

FIG. 8 shows the memory space and the address map. In FIG. 8, reference numeral 11 is a memory space of 4 GB capable of expressing the data by 32 bits, and m1 is a memory area used by the system. In this example, the memory area m1 has 1 MB. The address bits used at this time are the low-order 20 bits indicated by “A”, and the high-order 12 bits indicated by “B” are not used. “A” indicates the failure judgment target bits, and “B” indicates the unused bits. At this time, address information is stored in the memory 1 that is loaded on the semiconductor integrated circuit. Further, it is ascertained in advance that the higher 12 bits are not used within the semiconductor integrated circuit. Thus, as the failure judgment bit information J1 inputted in the first step ST1, numerical values as shown in the drawing may be inputted. In this failure judgment bit information J1, the failure judgment target bits A are all defined with “1”, indicating that the bits are the failure judgment targets, and the unused bits B are defined with “0”, indicating that the bits are out of the failure judgment targets.

In the test circuit generated by the test circuit generating method of this embodiment, only the necessary bits on the system are defined as the judgment target bits in case of designing a semiconductor integrated circuit by using a memory including the bits that are not used on the system. Herewith, it is possible to eliminate defect of the semiconductor integrated circuits due to the failures of the unused bit. Therefore, the yield can be improved.

Furthermore, the memory area m1 and the bit array of the failure judgment bit information J1 shown in FIG. 8 are merely examples, and the judgment target bits used in the test circuit generating method of the invention are not limited to them.

### Fifth Embodiment

A fifth embodiment of the present invention has a feature that the bits always outputting the same value among the outputs of the memory are defined as fixed-value bits, the value outputted from the fixed-value bits is defined as the fixed value, and the test circuit is generated by using such values. This is a structure achieved by focusing on the fact that the fixed-value bits that output the same value at all times can be excluded from the test target. When the expected value is “0” for the fixed value “1”, and the expected value is “1” for the fixed value “0”, those bits are excluded from the test target. At the fixed-value bits, failure judgment may be carried out only when the expected value is the same as the fixed value. When the values are inconsistent, the bit may be excluded from the failure judgment target.

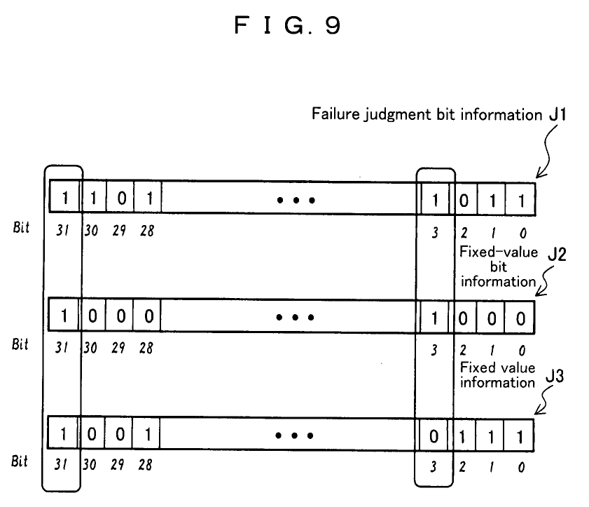

FIG. 9 shows the fixed-value bit information J2 and the fixed value information J3, in addition to the failure judgment bit information J1 that is shown in FIG. 3. The fixed-value bit information J2 indicates that the bit stores the fixed value. The bit is defined as the fixed-value bit with “1”, and defined as not being the fixed-value bit with “0”. The bit defined with “1” by the fixed-value bit information J2 is the fixed-value bit, and the value outputted from the fixed-value bit is defined by the fixed value information J3.

The fixed value information J3 indicates the value stored in the fixed-value bit. The fixed value information of that fixed-value bit is “1” when “1” is stored at all times and, the fixed value information of that fixed-value bit is “0” when “0” is stored at all times.

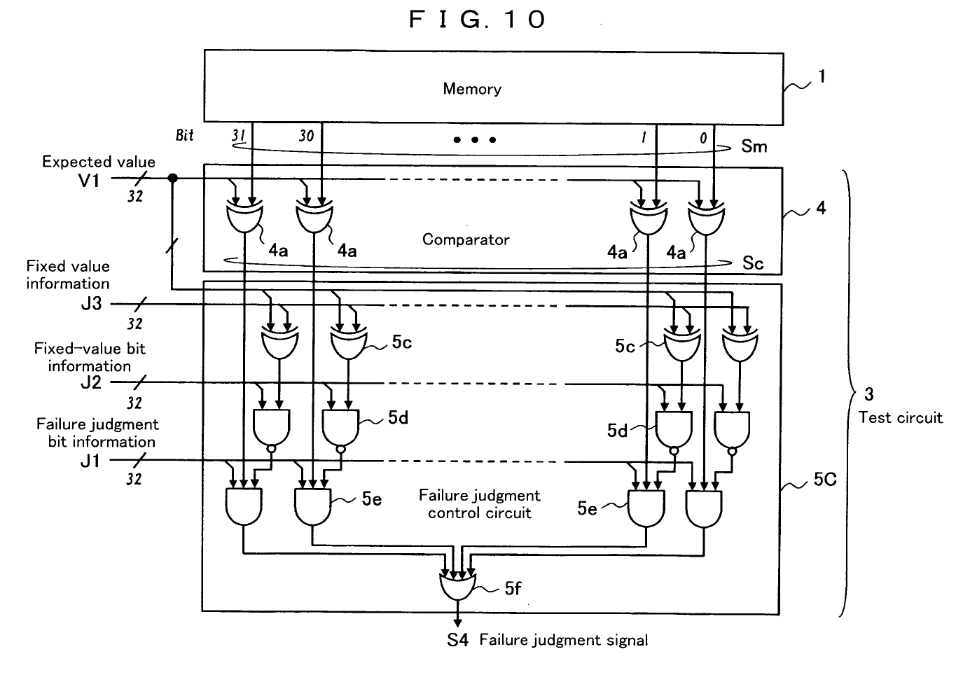

Looking at the bit 31 as an example, it is found that the bit 31 is the bit to be a target of failure judgment since the failure judgment bit information is “1”. Further, it is found that it is not the bit where the value “0” and the value “1” are switched depending on the condition and accordingly the bit 31 is fixed at either “0” or “1”, since the fixed-value bit information J2 is “1”. Moreover, it is found that the fixed value is “1” since the fixed value information J3 is “1”. As just described, since the value of the bit 31 in known in advance as “1”, failure judgment for that bit can be eliminated, i.e. it is unnecessary to perform failure judgment, under a malfunction state where “1” is outputted from the memory 1. Though it will be described later referring to FIG. 10, the fixed-value gate circuit 5c in the failure judgment control circuit 5C is constituted on the assumption that the bit where the fixed value is different from the expected value is excluded from the failure judgment target. In accordance with such assumption on the fixed-value gate circuit 5c, a fixed-value bit gate circuit 5d is constituted as follows. That is, the fixed-value bit gate circuit 5d judges that the bit is the one to be excluded from the failure judgment target, when the fixed value is different from the expected value at that fixed-value bit. A judgment target gate circuit 5e selectively performs only the failure judgment of the output data from the bit comparator 4 as the judgment target. At the bit 31, it is unnecessary to perform the test for outputting “0”. It is not necessary to judge it as a failure even if the bit cannot output “0” as long as it can output “1”.

Further, looking at the bit 3 in FIG. 9 as another example, it is found that the bit 3 is the bit to be a target of failure judgment since the failure judgment bit information J1 is “1”. Further, it is found that the bit 3 is the one where the value is fixed since the fixed-value bit information J2 is “1”, and the fixed value is “0” since the fixed value information J3 is “0”. The fixed value information J3 is defined as “0” at the bit 3, so that the test for outputting “1” is unnecessary.

Furthermore, looking at the bit 30 as another example, it is found that the bit 30 is the bit to be a target of failure judgment since the failure judgment bit information J1 is “1”. However, since the fixed-value bit information J2 is “0”, it is found that value of the bit 30 is not fixed, and it is the bit where the value “0” and the value “1” are switched depending on the condition. The concrete value of the fixed value information J3 in this case has no meaning specially.

Further, looking at the bit 29 as another example, it is found that the bit 29 can be excluded from the target of failure judgment since the failure judgment bit information J1 is “0”. The specific values of the fixed-value bit information J2 and the fixed value information J3 in this case have no meaning specially.

FIG. 10 shows an example of the test circuit 3 that uses the failure judgment bit information J1, the fixed-value bit information J2, and the fixed value information J3. The failure judgment control circuit 5C comprises the fixed-value gate circuit 5c, the fixed-value bit gate circuit 5d, the judgment target gate circuit 5e, and the failure judgment output circuit 5f. The fixed-value gate circuit 5c, the fixed-value bit gate circuit 5d and the judgment target gate circuit 5e are provided in each bit. The fixed-value gate circuit 5c is constituted with an exclusive OR circuit. The expected value V1 and the fixed value information J3 are inputted in increments of a bit to the fixed-value gate circuit 5c. The fixed-value gate circuit 5c judges whether or not the fixed value is inconsistent with the expected value based on the inputted information. The fixed-value bit gate circuit 5d is constituted with a circuit that inverts the output of the AND circuit. The output data of the fixed-value gate circuit 5c and the fixed-value bit information J2 are inputted in increments of a bit to fixed-value bit gate circuit 5d. When it is not the fixed-value bit, the fixed-value bit gate circuit 5d activates an input of the next-stage judgment target gate circuit 5e and, when it is the fixed-value bit, the fixed-value bit gate circuit 5d functions in such a manner that the inconsistency judgment outputted from the fixed-value gate circuit 5c is not outputted through the judgment target gate circuit 5e. The judgment target gate circuit 5e is constituted with an AND circuit with three inputs, which controls whether or not it allows to output the output data of the inconsistency detection circuit 4a based on the correlation between the failure judgment bit information J1 and the output data of the fixed-value bit gate circuit 5d. The judgment target gate circuit 5e performs the next judgment on the fixed value when there is a fixed-value bit in a state where it is known to be the failure judgment target bit. When the fixed value is consistent with the expected value, the bit is set as the target of the failure judgment by allowing a through of the output data of the inconsistency detection circuit 4a in the comparator 4 is let through to have that bit as the target of the failure judgment. In the meantime, when the fixed value is different from the expected value, that bit is excluded from the target of the failure judgment by rejecting a through of the output data of the inconsistency detection circuit 4a of the comparator 4. This judgment is based on the following knowledge. That is, in the case where it is a fixed value and also the failure judgment target bits, it can be judged as impossible and the bit can be excluded from the failure judgment target when the fixed value thereof is different from the expected value.

By taking such circuit structure, the input to the failure judgment output circuit 5f constituted with the OR circuit becomes “1” at all times, when the judgment target bit is “1”, the fixed-value bit information J2 is “1” and the expected value V1 and the fixed value information J3 are different. Thus, the bit is judged as the one with no failure.

Referring to the case of the bit shown in FIG. 9, it becomes as follows. First, as described above, in the bit where the failure judgment bit information J1 is “0”, the output of the judgment target gate circuit 5e becomes “0”. Thus, it is excluded from the target of the failure judgment.

Then, in the bit where the judgment target bit is “1”, when the value of the fixed-value bit information J2 is “0”, the output of the fixed-value bit gate circuit 5d becomes “1”. Thus, the inconsistency judgment data Sc from the comparator 4 is propagated to the failure judgment output circuit 5f. In the meantime, when the fixed-value bit information J2 is “1”, the result of comparison performed between the fixed value information J3 and the expected value V1 is propagated.

In the example of the bit 31 shown in FIG. 9, the failure judgment bit information J1 is “1”, the fixed-value bit information J2 is “1”, and the fixed value information J3 is also “1”. If the expected value V1 at this time is “1”, the output of the fixed-value gate circuit 5c becomes “0” and the output of the fixed-value bit gate circuit 5d becomes “1”. Thus, the inconsistency judgment data Sc from the comparator 4 is propagated to the output of the judgment target gate circuit 5e, so that it is judged as a failure. In the meantime, when the expected value V1 is “0”, the output of the fixed-value gate circuit 5c becomes “0” and the output of the fixed-value bit gate circuit 5d becomes “0”. Therefore, the output of the judgment target gate circuit 5e becomes “0”, so that the bit 31 is judged as no failure. That is, it is judged as no failure in the test where the expected value becomes an inversed value to the fixed value information J3, regardless of the result the comparator 4.

Through generating the test circuit by using the fixed-value bit information J2 and the fixed value information J3 in this manner, it becomes possible to eliminate misjudgments of the semiconductor integrated circuits that are judged as a failure by the test circuit generated by the conventional method when the expected value and the fixed value are different at the fixed-value bit. Therefore, the yield can be improved.

Further, the fixed-value bit information J2 and the fixed value information J3 may be stored in the register 6 shown in FIG. 6 so as to input the signals to the failure judgment control circuit 5C. Herewith, the effects similar to those described in the second embodiment can be expected.

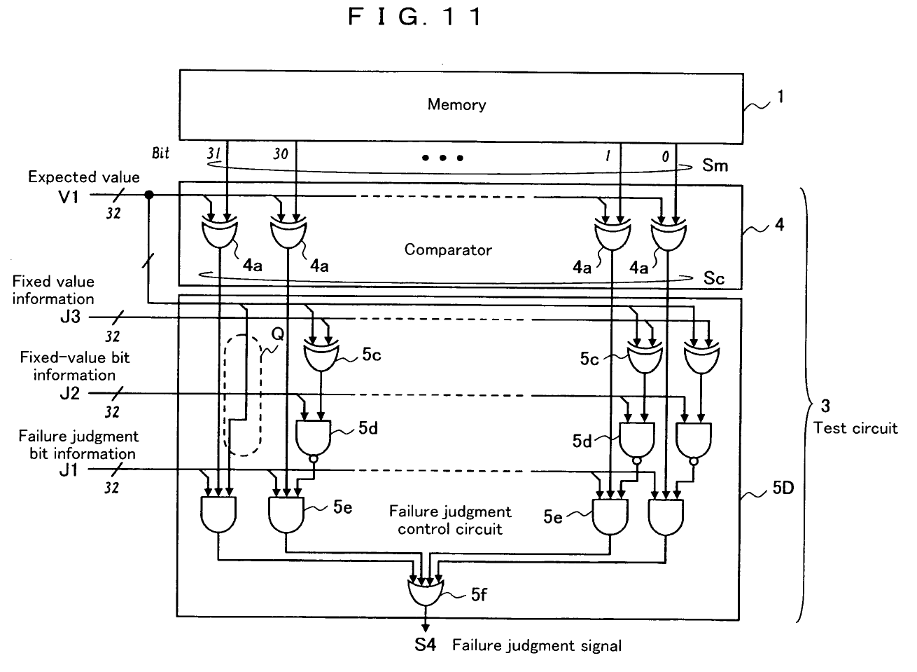

Furthermore, the test circuit 3 may be generated through inputting the fixed-value bit information J2 and the fixed value information J3 in the first step ST1. FIG. 11 shows the circuit structure in the case where a failure judgment control circuit 5D is generated in the second step ST2 according to the fixed-value bit information J2 and the fixed value information J3 shown in FIG. 9. According to FIG. 9, the bit 31 is a fixed-value bit, and the fixed value is “1”. By generating a circuit based thereupon, it is possible to omit the fixed-value gate circuit 5c and the fixed-value bit gate circuit 5d at the bit 31 as Q in FIG. 11.

Specifically, it can be described as follows. It is assumed herein that the value of the fixed-value bit information J2 is “1”, indicating that it is valid. When the fixed value is “0” and the expected value is “0”, the output of the fixed-value gate circuit 5c is “0”, and the output of the fixed-value bit gate circuit 5d becomes “1”. When the fixed value is “1” and the expected value is “0”, the output of the fixed-value gate circuit 5c is “1”, and the output of the fixed-value bit gate circuit 5d becomes “0”. When the fixed value is “0” and the expected value is “1”, the output of the fixed-value gate circuit 5c is “1”, and the output of the fixed-value bit gate circuit 5d becomes “0”. When the fixed value is “1” and the expected value is “1”, the output of the fixed-value gate circuit 5c is “0”, and the output of the fixed-value bit gate circuit 5d becomes “1”. The followings can be found by looking at those four states. That is, the output of the fixed-value bit gate circuit 5d becomes consistent with the expected value, assuming that the fixed value is “1”. In other words, the series circuit of the fixed-value gate circuit 5c and the fixed-value bit gate circuit 5d becomes equivalent to the bit line of the expected value. Thus, the fixed-value gate circuit 5c and the fixed-value bit gate circuit 5d can be omitted for the bit where the value of the fixed-value bit information J2 and the fixed value in the fixed-value information J3 are both “1”, indicating that it is valid. An input of the judgment target gate circuit 5e is connected to the bit line of the expected value.

By taking such structure, it becomes possible to optimize the failure judgment control circuit as in the case of the third embodiment of the present invention. Thus, the circuit area and the power consumption can be reduced. Besides, The circuit structure described in this embodiment is merely an example, and the structure of the circuit generated by the test circuit generating method according to the present invention is not limited to the structure described above.

### Sixth Embodiment

A sixth embodiment of the present invention is distinctive in the respect that the fixed-value bit information J2 and the fixed value information J3 determined based on the address map of the system are inputted in the first step ST1. Further, the memory 1 tested by the test circuit that is generated by the test circuit generating method of this embodiment is a memory for storing the address of the system.

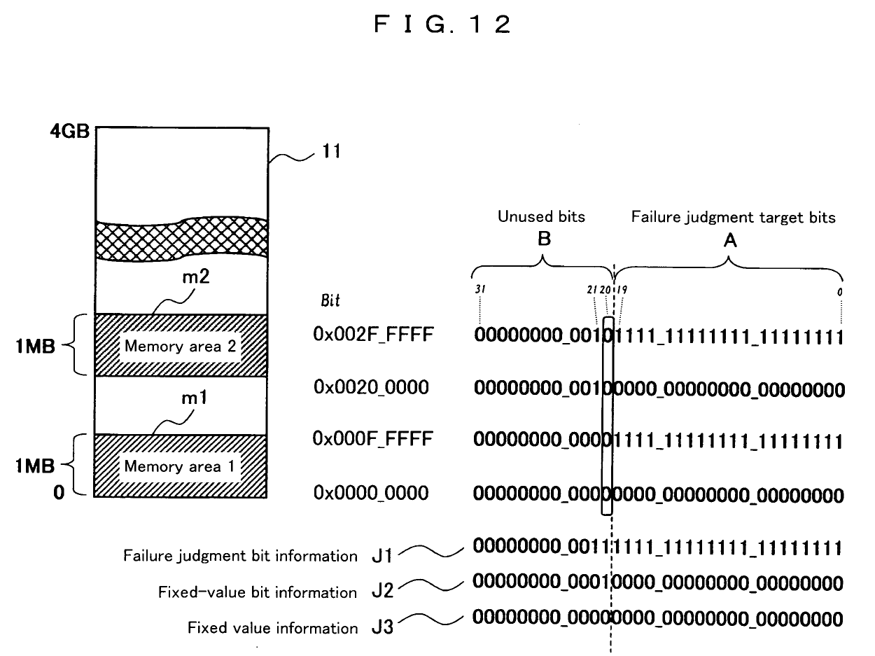

FIG. 12 shows the address map where a memory area m2 is defined in addition to the memory area in the address map shown in FIG. 8. At this time, the memory area m2 uses until the 21st bit of the address, so that the failure judgment information J1 becomes “1” from the 0th bit to the 21st bit. Further, the 20th bit is always “0”, so that “1” is never written to that bit in both cases where an access is made to the memory area m1 and to the memory area m2. Under such circumstances, the 20th bit is defined as the fixed-value bit, and defined as in the fixed-value bit information J2. Further, since the fixed value is “0”, the fixed value information J3 is defined in such a manner that the 20th bit becomes “0”. In the fixed value information J3, the bits other than the 20th bit are also defined as “0”. However, when the fixed-value bit information J2 is “0”, the bits other than the 20th bit are not used. Thus, it only requires the 20th bit to be “0”.

As just described, in generating the test circuit for testing the memory that stores the addresses of the system, the fixed-value bit information J2 and the fixed value information J3 are inputted according to the address map of the system. Herewith, it becomes unnecessary to test both values of “0” and “1” for the bits that always have the constant value on the address map of the system. As a result, it becomes possible to eliminate failure judgment of the semiconductor integrated circuits that are judged as a fault by the test circuit generated by the conventional method when the expected value and the fixed value are different at the fixed-value bit. Therefore, the yield can be improved.

Furthermore, the memory area, the judgment target bit, the fixed-value bit information and the fixed value information shown in FIG. 12 are merely illustrated as examples, and it is not limited to them.

### Seventh Embodiment

In a seventh embodiment of the present invention, the failure judgment bit information J1 is inputted in the first step ST1, and a comparator is generated in the second step ST2 based on the failure judgment bit information J1. This is to simplify the structure of the comparator.

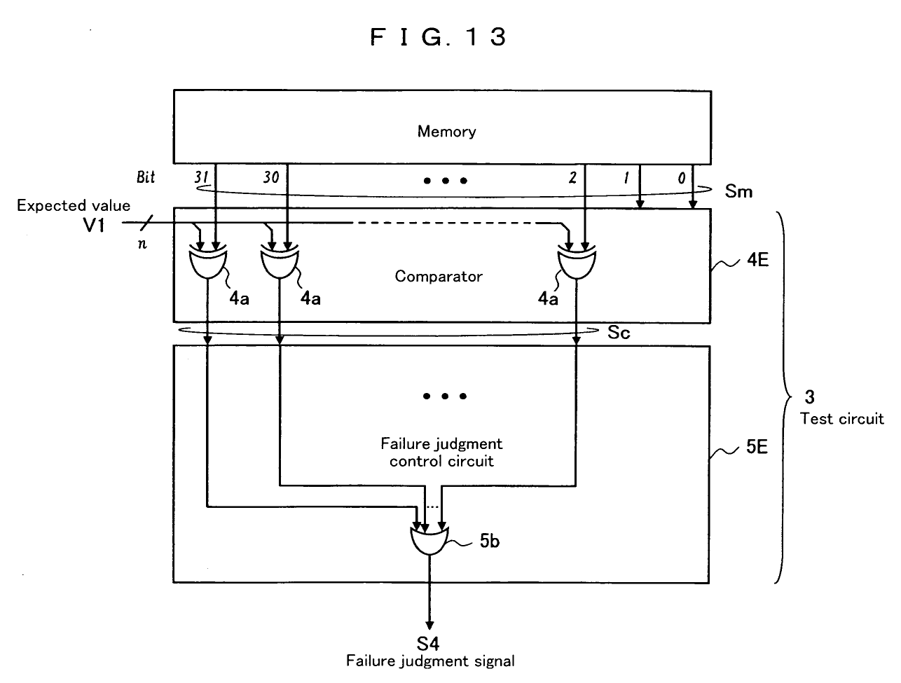

FIG. 13 shows an example of a comparator 4E generated in the second step. In the comparator 4E, only the necessary inconsistency detection circuit 4a are generated based on the value of the failure judgment bit information J1. It is structured that there is no inconsistency detection circuit 4a at the 0th bit and the 1st bit, so that it is necessary to provide the number of bits of the inputted expected value V1 as much as the number of bits that are defined so as to perform failure judgment in the failure judgment bit information J1. The failure judgment control circuit 5E comprises only the failure judgment output circuit 5b that is constituted with an OR circuit.

As just described, by generating only the necessary number of inconsistency detection circuits 4a based on the judgment target bits, the unnecessary inconsistency detection circuits 4a can be reduced. Thus, effects on reducing the circuit area and the power consumption can be expected. The circuit structure of the comparator 4E shown in FIG. 13 is merely an example, and it is not limited to that.

### Eighth Embodiment

An eighth embodiment of the present invention is distinctive in the respect that the comparator is generated in the second step ST2 based on the fixed-value bit information J2 and the fixed value information J3 which are inputted in the first step ST1.

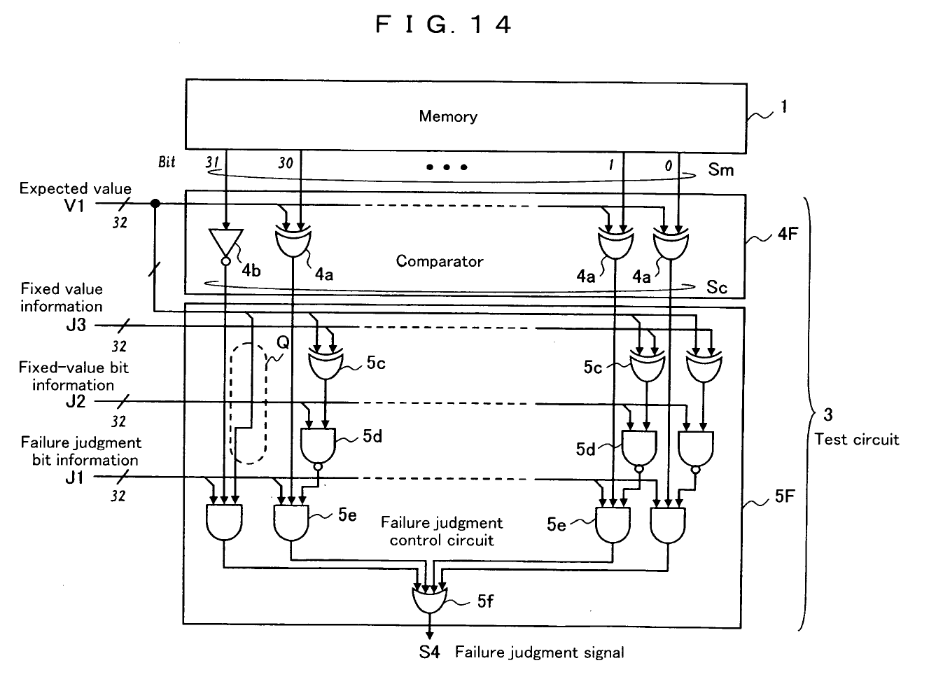

FIG. 14 shows an example of a comparator 4F that is generated in the second step ST2 according to this embodiment. In the comparator 4F shown in FIG. 14, the inconsistency detection circuit 4a at the bit 31 is simplified based on the fixed-value bit information J2 and the fixed value information J3, and this part is achieved with an inverter 4b. In this embodiment, it is known in advance that the output of the bit 31 is “1” at all times. Thus, it may be judged as a failure only when the output of the bit 31 becomes “0”. Thus, it is possible to achieve the inconsistency detection circuit 4a with the inverter 4b. Like the case of FIG. 11, in the failure judgment control circuit 5F, the bit 31 is a fixed-value bit and the fixed value is “1”. Thus, it is possible to omit the fixed-value gate circuit 5c and the fixed-value gate circuit 5d at the bit 31 as Q. An input to the judgment target gate circuit 5e is connected to the bit line of the expected value. The circuit structure of the comparator 4F shown in FIG. 14 is merely an example of the case formed in accordance with the example of the fixed value shown in FIG. 9, and it is not limited to that.

### Ninth Embodiment

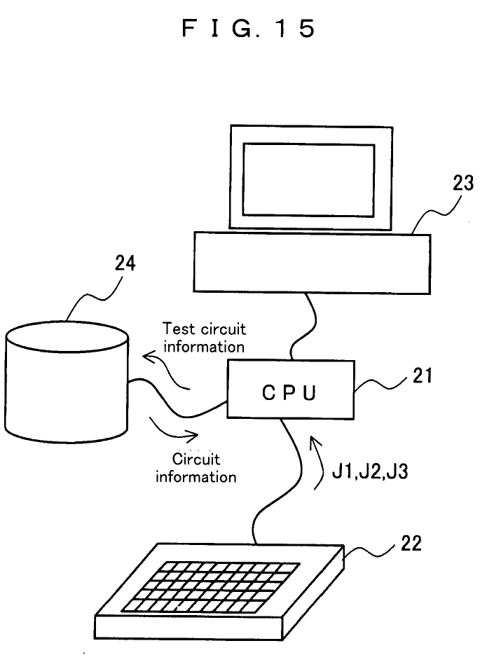

FIG. 15 is a constitutive diagram on the system of a test circuit generating device in a semiconductor integrated circuit according to a ninth embodiment of the present invention. This system comprises a processing device (CPU) 21, an input device (keyboard) 22, an output device (display) 23, and a storage device (disk) 24. In each of the test circuit generating method according to the embodiments, the failure judgment bit information J1, the fixed-value bit information J2 and the fixed value information J3 are inputted by using the input device 22, the information of the semiconductor integrated circuit is read out from the storage device 24, the test circuit is generated by the processing device 21, and the processing result is outputted to the output device 23. The test circuit information is saved in the storage device 24. As just described, like the designing of the semiconductor integrated circuit, it is possible to perform generation of the test circuit in accordance with the test circuit generating method.

The present invention has been described in detail referring to the most preferred embodiments. However, various combinations and modifications of the components are possible without departing from the spirit and the broad scope of the appended claims.

What is claimed is:

1. A method for generating a test circuit in a semiconductor integrated circuit, that is a test circuit for testing a semiconductor integrated circuit that comprises a memory is generated, said method comprising the steps of:
a first step for obtaining memory information containing structural information of said memory;
a second step for obtaining failure judgment bit information that designates a judgment target bit taken as a target of failure judgment from entire output bits of said memory; and
a third step for generating a failure judgment control circuit that performs failure judgment to said memory by using only said judgment target bit designated in said failure judgment bit information, referring to said memory information.

2. The method for generating a test circuit for a semiconductor integrated circuit according to claim 1, wherein a register for storing said failure judgment bit information is additionally generated in said third step.

3. The method for generating a test circuit for a semiconductor integrated circuit according to claim 1, wherein said second step and said third step are performed in a same step.

4. The method for generating a test circuit for a semiconductor integrated circuit according to claim 1, wherein said first step and said second step are performed in a same step.

5. The method for generating a test circuit for a semiconductor integrated circuit according to claim 3, wherein:
said memory stores memory addresses based on an address map of a system that is achieved by said semiconductor integrated circuit; and
failure judgment bit information determined based on said addresses is used as said failure judgment information in said first step.

6. The method for generating a test circuit for a semiconductor integrated circuit according to claim 1, wherein a comparator, that compares only output of said judgment target bit with an expected value thereof by using said judgment target bit designated in said failure judgment bit information, is generated in said third step.

7. A method for generating a test circuit for a semiconductor integrated circuit wherein a test circuit for testing a semiconductor integrated circuit that comprises a memory is generated, said method comprising the steps of:
a first step for obtaining memory information containing structural information of said memory;
a second step for obtaining fixed-value bit information that designates a fixed-value bit at which an output value from said memory becomes a fixed value of either “0” or “1”, and obtaining fixed value information that designates a fixed value that is an output value of said fixed-value bit; and
a third step for generating a failure judgment control circuit that performs failure judgment when an expected value of said fixed-value bit is consistent with said fixed value designated in said fixed value information, referring to said memory information.

8. The method for generating a test circuit for a semiconductor integrated circuit according to claim 7, wherein:
in said second step, failure judgment bit information, that designates a judgment target bit taken as a target of failure judgment from entire output bits of said memory, is further obtained; and
said failure judgment control circuit is generated in said third step when an expected value of said fixed-value bit is consistent with a fixed value designated in said fixed value information, and said judgment target bit in said failure judgment bit information is valid.

9. The method for generating a test circuit for a semiconductor integrated circuit according to claim 7, wherein a register for storing said fixed-value bit information and said fixed value information is generated in said third step.

10. The method for generating a test circuit for a semiconductor integrated circuit according to claim 8, wherein:
said memory stores memory addresses based on an address map of a system that is achieved by said semiconductor integrated circuit; and
in said first step, a bit whose value becomes either “0” or “1” at all times from all of said memory addresses stored in said memory, is obtained as said fixed-value bit.

11. The method for generating a test circuit for a semiconductor integrated circuit according to claim 7, wherein, in said third step, a comparator which compares only output of said judgment target bit with an expected value thereof by using said judgment target bit designated in said failure judgment bit information, is generated.

12. The method for generating a test circuit for a semiconductor integrated circuit according to claim 7, wherein a comparator, that excludes a comparison between an output value of said fixed-value bit and an expected value thereof by using said fixed-value bit designated in said fixed-value bit information, is generated in said third step.

13. A method for generating a test circuit for a semiconductor integrated circuit that is a method for generating a test circuit for testing a semiconductor integrated circuit that comprises a memory, is generated, said method comprising the steps of:
a first step for obtaining memory information containing structural information of said memory;
a second step for obtaining fixed-value bit information that designates a fixed-value bit at which an output value of said memory becomes a fixed value of either “0” or “1” from entire output bits of said memory, and obtaining fixed value information that designates a fixed value that is an output value of said fixed-value bit from said entire output bits of said memory; and
a third step for generating a failure judgment control circuit that performs failure judgment to said memory by using said fixed-value bit information and said fixed value information, referring to said memory information.

14. The method for generating a test circuit for a semiconductor integrated circuit according to claim 13, wherein:
said memory stores memory addresses based on an address map of a system that is achieved by said semiconductor integrated circuit; and
in said first step, a bit whose value becomes either “0” or “1” at all times in all of said memory addresses capable of being stored in said memory, is obtained as said fixed-value bit.

15. The method for generating a test circuit for a semiconductor integrated circuit according to claim 13, wherein a comparator, that compares only output of said judgment target bit with an expected value thereof by using said judgment target bit designated in said failure judgment bit information, is generated in said third step.

16. The method for generating a test circuit for a semiconductor integrated circuit according to claim 13, wherein a comparator, that excludes a comparison between an output value of said fixed-value bit and an expected value thereof by using said fixed-value bit designated in said fixed-value bit information, is generated in said third step.

17. A device for generating a test circuit for a semiconductor integrated circuit, that is the device for generating a test circuit for testing a semiconductor integrated circuit that comprises a memory, said device comprising:
a first information obtaining device for obtaining memory information containing structural information of said memory;
a second information obtaining device for obtaining failure judgment bit information that designates a judgment target bit taken as a target of failure judgment from entire output bits of said memory; and
a circuit generator for generating a failure judgment control circuit that performs failure judgment to said memory by using only said judgment target bit designated in said failure judgment bit information, referring to said memory information.

18. The device for generating a test circuit for a semiconductor integrated circuit according to claim 17, wherein said circuit generator generates a register for storing said failure judgment bit information.

19. The device for generating a test circuit for a semiconductor integrated circuit according to claim 17, wherein said first information obtaining device and said second information obtaining device are constituted as a single structure.

20. The device for generating a test circuit for a semiconductor integrated circuit according to claim 17, wherein said second information obtaining device and said circuit generator are constituted as a single structure.

21. The device for generating a test circuit for a semiconductor integrated circuit according to claim 19, wherein:
said memory stores memory addresses based on an address map of a system that is achieved by said semiconductor integrated circuit; and
said first information obtaining device uses failure judgment bit information determined based on said address map employed in a system that is achieved by said semiconductor integrated circuit as said failure judgment information.

22. The device for generating a test circuit for a semiconductor integrated circuit according to claim 20, wherein said circuit generator generates a comparator that compares only output of said judgment target bit with an expected value thereof by using said judgment target bit designated in said failure judgment bit information.

23. A device for generating a test circuit for a semiconductor integrated circuit, that is the device for generating a test circuit for testing a semiconductor integrated circuit that comprises a memory, said device comprising:
a first information obtaining device for obtaining memory information containing structural information of said memory;
a second information obtaining device for obtaining fixed-value bit information that designates a fixed-value bit at which an output value of said memory becomes a fixed value of either “0” or “1”, and obtaining fixed value information that designates a fixed value that is an output value at said fixed-value bit; and
a circuit generator for generating a failure judgment control circuit that performs failure judgment when an expected value of said fixed-value bit is consistent with said fixed value designated in said fixed value information, referring to said memory information.

24. The device for generating a test circuit for a semiconductor integrated circuit according to claim 23, wherein:
said second information obtaining device further obtains failure judgment bit information that designates a judgment target bit taken as a target of failure judgment from entire output bits of said memory; and
said circuit generator generates said failure judgment control circuit, when an expected value of said fixed-value bit is consistent with said fixed value designated in said fixed value information, and said judgment target bit in said failure judgment bit information is valid.

25. The device for generating a test circuit for a semiconductor integrated circuit according to claim 23, wherein said circuit generator generates a register for storing said fixed-value bit information and said fixed value information.

26. The device for generating a test circuit for a semiconductor integrated circuit according to claim 24, wherein:
said memory stores memory addresses based on an address map of a system that is achieved by said semiconductor integrated circuit; and
said first information obtaining device obtains a bit whose value becomes either “0” or “1” at all times from all of said memory addresses stored in said memory, as said fixed-value bit.

27. The device for generating a test circuit for a semiconductor integrated circuit according to claim 23, wherein said circuit generator generates a comparator that compares only output of said judgment target bit with an expected value thereof by using said judgment target bit designated in said failure judgment bit information.

28. The device for generating a test circuit for a semiconductor integrated circuit according to claim 23, wherein said circuit generator generates a comparator that excludes a comparison between an output value of said fixed-value bit and an expected value thereof by using said judgment target bit designated in said failure judgment bit information.

29. A device for generating a test circuit for a semiconductor integrated circuit, that is the device for generating a test circuit for testing a semiconductor integrated circuit that comprises a memory, said device comprising:
a first information obtaining device for obtaining memory information containing structural information of said memory;
a second information obtaining device for obtaining fixed-value bit information that designates a fixed-value bit at which an output value of said memory becomes a fixed value of either “0” or “1” from entire output bits of said memory, and obtaining fixed value information designating a fixed value that is an output value of said fixed-value bit; and
a circuit generator for generating a failure judgment control circuit that performs failure judgment of said memory by using said fixed-value bit information and said fixed value information, referring to said memory information.

30. The device for generating a test circuit for a semiconductor integrated circuit according to claim 29, wherein:
said memory stores memory addresses based on an address map of a system that is achieved by said semiconductor integrated circuit; and
said first information obtaining device obtains a bit whose value becomes either “0” or “1” at all times in all of said memory addresses capable of being stored in said memory, as said fixed-value bit.

31. The device for generating a test circuit for a semiconductor integrated circuit according to claim 29, wherein said circuit generator generates a comparator that compares only output of said judgment target bit with an expected value thereof by using said judgment target bit designated in said failure judgment bit information.

32. The device for generating a test circuit for a semiconductor integrated circuit according to claim 29, wherein said circuit generator generates a comparator that excludes a comparison between an output value of said fixed-value bit and an expected value thereof by using said fixed-value bit designated in said fixed-value bit information.

33. A semiconductor integrated circuit, comprising:
a memory;
a comparator for comparing output data of each bit in said memory with an expected value thereof; and
a failure judgment control circuit that performs output control of comparison results for each bit obtained by said comparator, based on the bits that are designated as judgment targets among entire output bits of said memory in a failure judgment bit information that designates a judgment target bit taken as a failure judgment target.

34. The semiconductor integrated circuit according to claim 33, further comprising a register for storing said failure judgment bit information.

35. A semiconductor integrated circuit, comprising:
a memory;
a comparator for comparing output data of each bit in said memory with an expected value thereof respectively; and
a failure judgment control circuit for selectively letting through a comparison result that is outputted by said comparator in accordance with judgment target bit in failure judgment bit information that designates a judgment target bit taken as a target of failure judgment.

36. A semiconductor integrated circuit, comprising:
a memory;
a comparator for comparing output data of each bit in said memory with an expected value thereof respectively; and
a failure judgment control circuit, wherein said failure judgment control circuit comprises:
a fixed-value gate circuit for respectively comparing a fixed value of each bit in fixed value information that designates an output value of a fixed-value bit where an output value from said memory is fixed at either “0” or “1”, with an expected value thereof; and
a fixed-value bit gate circuit for controlling output of said fixed-value gate circuit, based on fixed-value bit information that designates said fixed-value bit and a value of each bit designated in said fixed-value bit information.

37. A semiconductor integrated circuit, comprising:
a memory;
a comparator for comparing output data of each bit in said memory with an expected value thereof respectively; and
a failure judgment control circuit, wherein said failure judgment control circuit comprises:
a fixed-value gate circuit for respectively comparing a fixed value of each bit in fixed value information that designates an output value of a fixed-value bit where an output value from said memory is fixed at either “0” or “1”, with an expected value thereof;
a fixed-value bit gate circuit for controlling output of said fixed-value gate circuit, based on a value of each bit in fixed-value bit information that designates said fixed-value bit; and
a judgment target gate circuit for controlling output of a comparison result obtained by said comparator, based on an output value of said fixed-value bit gate circuit and judgment target bit designated in said failure judgment bit information.

38. The semiconductor integrated circuit according to claim 36, wherein processing by said fixed-value gate circuit and said fixed-value bit gate circuit is both omitted for a bit whose value in said fixed-value bit information and said fixed value thereof in said fixed value information are both valid, and said fixed value of said bit is treated as output data thereof.

39. The semiconductor integrated circuit according to claim 37, wherein processing by said fixed-value gate circuit and said fixed-value bit gate circuit is both omitted for a bit whose value in said fixed-value bit information and said fixed value thereof in said fixed value information are both valid, and said fixed value of said bit is treated as output data thereof.

40. The semiconductor integrated circuit according to claim 33, wherein, output data of a bit that does not correspond to said judgment target bit is neglected to be inputted to said comparator, and output control through said failure judgment control circuit to said comparator at a bit corresponding to said judgment target bit is omitted.

41. The semiconductor integrated circuit according to claim 36, wherein, for a bit whose value in said fixed-value bit information and said fixed value in said fixed value information are both valid, processing of said fixed-value gate circuit and processing of said fixed-value bit gate circuit is both omitted, and processing of said comparator at said bit is substituted with processing performed by a logic inverting circuit.

42. The semiconductor integrated circuit according to claim 37, wherein, for a bit whose value in said fixed-value bit information and said fixed value in said fixed value information are both valid, processing of said fixed-value gate circuit and processing of said fixed-value bit gate circuit is both omitted, and processing of said comparator at said bit is substituted with processing performed by a logic inverting circuit.
